(19) United States
(12) Patent Application Publication
(10) Pub. No.: US 2024/0379525 A1
(43) Pub. Date: Nov. 14, 2024

(54) SEMICONDUCTOR PACKAGE STACK AND A METHOD FOR FORMING THE SAME

(71) Applicant: STATS ChipPAC Pte. Ltd., Singapore (SG)

(72) Inventors: YoungGeun KIM, Incheon (KR); MingYu KIM, Incheon (KR)

(21) Appl. No.: 18/658,966

(22) Filed: May 8, 2024

(30) Foreign Application Priority Data
May 12, 2023 (CN) 202310536338.8

(51) Int. Cl. H01L 23/498; H01L 23/00; H01L 23/31; H01L 25/10

(52) U.S. Cl. CPC H01L 23/49838; H01L 23/3121; H01L 23/49811; H01L 25/105; H01L 24/16; H01L 24/32; H01L 24/73; H01L 2224/16225; H01L 2224/32225; H01L 2224/73204; H01L 2225/1058; H01L 2924/1815

(57) ABSTRACT

A semiconductor package stack comprises: a base substrate having one or more sets of base conductive patterns on its front surface; an anisotropic conductive film formed on the front surface of the base substrate; one or more semiconductor packages disposed on the base substrate via the anisotropic conductive film, wherein each of the one or more semiconductor packages comprises package interconnect structures which have package conductive patterns exposed from a lateral surface of the semiconductor package; and wherein the package conductive patterns are aligned with base conductive patterns; and a vertical substrate disposed on the base substrate via the anisotropic conductive film, wherein the vertical substrate comprises vertical interconnect structures which have vertical conductive patterns exposed from a lateral surface of the vertical substrate; and wherein the vertical conductive patterns are aligned with base conductive patterns.

### TECHNICAL FIELD

The present application generally relates to semiconductor technology, and more particularly, to a semiconductor package stack and a method for forming a semiconductor package stack.

### BACKGROUND OF THE INVENTION

The semiconductor industry is constantly faced with complex integration challenges as consumers want their electronics to be smaller, faster and higher performance with more and more functionalities packed into a single device. This raises problems such as finding space to route traces along a printed circuit board (PCB) and integrating functionality into silicon integrated circuit devices.

Therefore, a need exists for an improved semiconductor package.

### SUMMARY OF THE INVENTION

An objective of the present application is to provide a semiconductor package stack to further improve integration and reduce difficulty in the internal wiring design.

According to an aspect of the present application, a semiconductor package stack is provided. The semiconductor package stack comprises: a base substrate having one or more sets of base conductive patterns on its front surface; an anisotropic conductive film formed on the front surface of the base substrate; one or more semiconductor packages disposed on the base substrate via the anisotropic conductive film and extending vertically relative to the front surface of the base substrate, wherein each of the one or more semiconductor packages comprises a set of package interconnect structures which have a set of package conductive patterns exposed from a lateral surface of the semiconductor package; and wherein the set of package conductive patterns are aligned with a set of base conductive patterns to allow electrical connection therebetween via the anisotropic conductive film; and a vertical substrate disposed on the base substrate via the anisotropic conductive film and extending vertically relative to the front surface of the base substrate, wherein the vertical substrate comprises a set of vertical interconnect structures which have a set of vertical conductive patterns exposed from a lateral surface of the vertical substrate; and wherein the set of vertical conductive patterns are aligned with a set of base conductive patterns to allow electrical connection therebetween via the anisotropic conductive film.

According to another aspect of the present application, a method for forming a semiconductor package stack is provided. The method comprises: stacking one or more semiconductor packages with a vertical substrate, to align their respective lateral surfaces with each other in a horizontal direction, wherein each of the semiconductor packages comprises a set of package interconnect structures which have a set of package conductive patterns exposed from the lateral surface of the semiconductor package; and the vertical substrate comprises a set of vertical conductive patterns exposed from the lateral surface of the vertical substrate; providing a base substrate having one or more sets of base conductive patterns on its front surface; forming an anisotropic conductive film on the front surface of the base substrate; and attaching vertically the stack of the one or more semiconductor packages and the vertical substrate onto the front surface of the base substrate via the anisotropic conductive film, such that the sets of package conductive patterns and the set of vertical conductive patterns on the respective lateral surfaces of the one or more semiconductor packages and the vertical substrate are aligned with the one or more sets of base conductive patterns on the front surface of the base substrate to allow electrical connection therebetween via the anisotropic conductive film.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a semiconductor package stack 100 according to an embodiment of the present application.

FIGS. 2A and 2B illustrate an interposer with package interconnect structures according to an embodiment of the present application.

FIG. 3 illustrates a semiconductor package stack 300 according to an embodiment of the present application.

FIGS. 4A to 4C illustrate a method for forming a semiconductor package according to an embodiment of the present application.

FIGS. 5A to 5C illustrate a method for forming a semiconductor package according to another embodiment of the present application.

FIGS. 6A to 6E illustrate a method for forming a semiconductor package stack according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

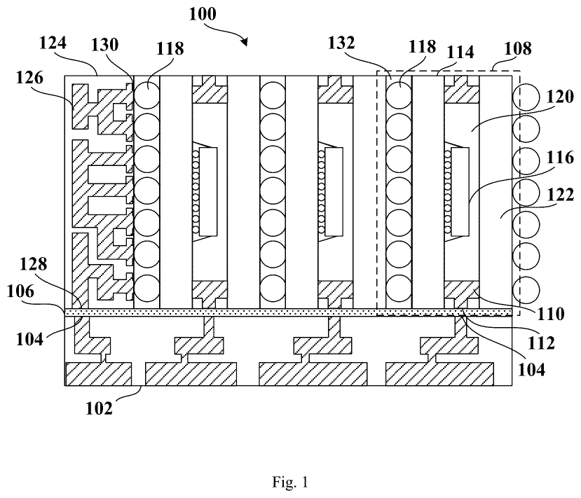

FIG. 1 illustrates a semiconductor package stack 100 according to an embodiment of the present application, which is a cross sectional view of the semiconductor package stack 100.

As shown in FIG. 1, the semiconductor package stack 100 includes a base substrate 102 where various semiconductor packages such as semiconductor packages 108 are stacked. The base substrate 102 extends in a horizontal direction of FIG. 1, and each of the semiconductor packages stacked on the base substrate 102 extends in a vertical direction of FIG. 1, i.e., substantially perpendicular to the base substrate 102. The base substrate 102 can provide support and connectivity for the semiconductor packages mounted thereon. By way of example, the base substrate 102 can include a printed circuit board (PCB), a carrier substrate, a semiconductor substrate with electrical interconnections, or a ceramic substrate. In some other examples, the base substrate 102 may include a laminate interposer, a strip interposer, a leadframe, or other suitable substrates.

In particular, the base substrate 102 may include one or more insulating or passivation layers, one or more conductive vias formed through the insulating layers, and one or more conductive layers formed over or between the insulating layers. The conductive vias and conductive layers form together various base interconnect structures in the base substrate 102. Furthermore, the base interconnect structures may include one or more sets of base conductive patterns 104 which are exposed from a front surface of the base substrate 102, as shown in FIG. 1. For example, the base conductive patterns 104 may take the form of contact pads or other similar structures. Each set of base conductive patterns 104 may be used to establish electrical connection with a semiconductor package disposed on the base substrate 102, as will be elaborated in more details below.

An anisotropic conductive film 106 is formed on the front surface of the base substrate 102. The anisotropic conductive film 106 is a curable material such as a thermoplastic or ultraviolet (UV) curable polymer composite material (epoxy, acryl, etc.) with special conductive particles such as micro solder balls distributed in the material. After being cured by heat, UV or pressure, the conductive particles in the anisotropic conductive film 106 can aggregate in its thickness direction and thus provide vertical electrical paths. However, the conductive particles in the anisotropic conductive film 106 are distributed far apart thus not electrically conductive in its plane direction (x&y-direction). It can be appreciated that the anisotropic conductive film 106 allows low height and fine pitch which enables high density and miniaturizing of the semiconductor package stack 100.

With continued reference to FIG. 1, three semiconductor packages 108 are disposed on the base substrate 102 via the anisotropic conductive film 106. These semiconductor packages 108 are all extending vertically relative to the front surface of the base substrate 102, and are assembled together through respective interposers. Such assembled and vertically extending packages can reduce the occupation of space on the base substrate 102, thus improving the level of integration of the semiconductor package stack 100.

Each semiconductor package 108 may include some package interconnect structures 110 embedded within an insulating material of the semiconductor package 108. In the embodiment, two sets of package interconnect structures 110 are illustrated, i.e., an upper set of package interconnect structures which are formed close to a top lateral surface of the semiconductor package 108 and a lower set of package interconnect structures which are formed close to a bottom lateral surface of the semiconductor package 108. The “lateral surface” herein refers to a surface of the semiconductor package that is substantially perpendicular to a package substrate of the semiconductor package, i.e., as relative to a front surface and a back surface which are generally extending in parallel with a plane of the package substrate. For a cuboid semiconductor package such as the semiconductor package 108, it has four lateral surfaces except a front surface and a back surface. In some embodiments, the package interconnect structures may be exposed from all the four lateral surfaces.

In particular, each of the bottom sets of package interconnect structures 110 have a set of package conductive patterns 112 exposed from the bottom lateral surface of the semiconductor package 108. In order to electrically connect the semiconductor package 108 with the base substrate 102, the exposed set of package conductive patterns 112 may be aligned with a set of base conductive patterns 104, as shown in FIG. 1. In this way, when a force is applied to the semiconductor package 108 towards the base substrate 102, the anisotropic conductive film 106 can create respective vertical electrical paths between the aligned package conductive patterns 112 and base conductive patterns 104, without any horizontal electrical paths in the anisotropic conductive film 106.

Each semiconductor package 108 may include a package substrate 114 having one or more electronic components 116 mounted on its front surface and package connectors 118 such as solder bumps mounted on its back surface. By way of example, the package substrate 114 can include a PCB, a carrier substrate, a semiconductor substrate with electrical interconnections, or a ceramic substrate. In some other examples, the package substrate 114 may include a laminate interposer, a strip interposer, a leadframe, or other suitable substrates. In some embodiments, the electronic components 116 may include active components such as semiconductor dice or smaller semiconductor packages, or passive components such as resistors, capacitors, connectors, antennas or the like. Although only one electronic component 116 is shown in FIG. 1 mounted on the package substrate 114, one or more another electronic components can be mounted thereon. An encapsulant layer 120 is formed on the front surface of the package substrate 114 to encapsulate the electronic components 116. Furthermore, an interposer 122 is disposed on a front surface of the encapsulant layer 120. That is, the semiconductor package 108 has a sandwich-like structure that encloses the electronic components 116 inside the semiconductor package 108. In the embodiment, the rightmost semiconductor package 108, which is also outermost of the semiconductor package stack 100, has on the front surface of the interposer 122 another set of solder bumps or the like, to further connect the semiconductor package 108 with other external devices (not shown). However, in some alternative embodiments, the outermost semiconductor package may not have such other external connectors. In that case, the semiconductor package stack 100 may be connected to other external devices via the base interconnect structures in the base substrate 102. For example, the base interconnect structures may have conductive patterns exposed from the back surface of the base substrate 102.

The package interconnect structures 110 of each semiconductor package 108 may be formed in the encapsulant layer 120, which is the middle layer of the semiconductor package 108. In this way, each package interconnect structure 110 may have three conductive patterns exposed from three respective surfaces of the encapsulant layer 120, i.e., the front surface adjacent to the interposer 122, the back surface adjacent to the package substrate 114 and the lateral surface adjacent to the anisotropic conductive film 106. In other words, each package interconnect structure 110 may take the form of a metal pillar with a branch. In this way, the interposer 122 and the package substrate 114 can be electrically coupled to each other via the package interconnect structures 110, and can be further electrically coupled to the base substrate 102.

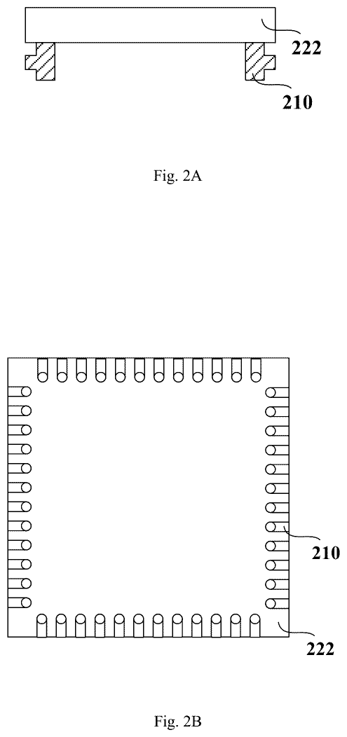

FIGS. 2A and 2B illustrate an interposer 222 with package interconnect structures 210 according to an embodiment of the present application. In some embodiments, the package interconnect structures 210 may be attached onto the interposer 222 before they are mounted onto a package substrate. For example, the package interconnect structure 210 may be bonded onto the conductive patterns of the interposer 222 via solder material (not shown). The package interconnect structures 210 may have a desired layout that is in compliance with a layout of the conductive patterns of the package substrate and the interposer to be connected. For example, as shown in FIG. 2B, the package interconnect structures 210 are distributed at four sides of the interposer 222, each of which has a branch extending to the periphery of the interposer 222. In this way, the semiconductor package incorporating such interposer 222 and package interconnect structures 210 may be electrically connectable at four sides. It can be appreciated that the package interconnect structures 210 may be formed in other layouts. For example, the package interconnect structures 210 may be formed at only one, two or three sides of the interposer 222. Moreover, some of the package interconnect structures 210 may be conductive pillars with no branches, or may be conductive pillars with two or more branches.

It can be appreciated that, the semiconductor package stack 100 includes a layer of semiconductor packages disposed on a base substrate 102, however, one or more other layers of semiconductor packages may be further stacked on the layer of semiconductor packages to further improve integration of the semiconductor package stack. Moreover, although it is shown only three semiconductor packages which are arranged in a row, an array of semiconductor packages may be formed by arranging the semiconductor packages in multiple rows and columns in one layer, and each adjacent two semiconductor packages may be electrically connected with each other, for example, through their respective package interconnect structures that are aligned with each other. For example, as shown in FIG. 2B, each semiconductor package may have package interconnect structures formed at its four lateral sides. In addition, in some embodiments, the anisotropic conductive film may not be extending over an entirety of the front surface of the base substrate, but over a portion of the front surface of the base substrate where electrical connection to the semiconductor packages may be desired.

Still referring to FIG. 1, a vertical substrate 124 may be disposed on the base substrate 102 via the anisotropic conductive film 106. Similar as the semiconductor packages 108, the vertical substrate 124 also extends vertically in relation to the front surface of the base substrate 102. In a preferred embodiment, the vertical substrate 124 may have a length and a width the same as those of the semiconductor packages 108 also mounted on the base substrate 102. In that case, the semiconductor package stack 100 may have a flat top surface. It can be appreciated that if two or more layers of semiconductor packages are mounted on the base substrate 102, the vertical substrate 124 may extend across the two or more layers of semiconductor packages.

In some examples, the vertical substrate 124 can include a PCB, a carrier substrate, a semiconductor substrate with electrical interconnections, or a ceramic substrate. In some other examples, the vertical substrate 124 may include a laminate interposer, a strip interposer, a leadframe, or other suitable substrates. The vertical substrate 124 may have a set of vertical interconnect structures 126 which are electrically connected to a semiconductor package 108 adjacent to the vertical substrate 124. In some embodiments, the set of vertical interconnect structures 126 may include a set of vertical conductive patterns 128 exposed from a lateral surface of the vertical substrate 124, and the vertical conductive patterns 128 may be further aligned with a set of base conductive patterns 104 to allow electrical connection therebetween via the anisotropic conductive film 106. In some alternative embodiments, the vertical interconnect structures 126 may not be aligned with and connected with the base conductive patterns 104. Moreover, the vertical interconnect structures 126 may have another set of vertical conductive patterns 130 exposed from a front surface of the vertical substrate 124, which are electrically connected with the package connectors 118 of the semiconductor package 108 adjacent to the vertical substrate 124.

After the semiconductor packages 108 and the vertical substrate 124 are assembled together and attached onto the base substrate 102, an insulative filler material 132 may be formed on the back surfaces of the semiconductor packages 108 and around the package connectors 118 which are internal to the semiconductor package stack 100, to provide insulation and protection for them. The filler material 132 also improves the firmness of the entire semiconductor package stack 100. Furthermore, in some alternative embodiments, the insulative filler material 132 may be formed prior to the attachment of the semiconductor packages 108 and the vertical substrate 124 to the base substrate 102.

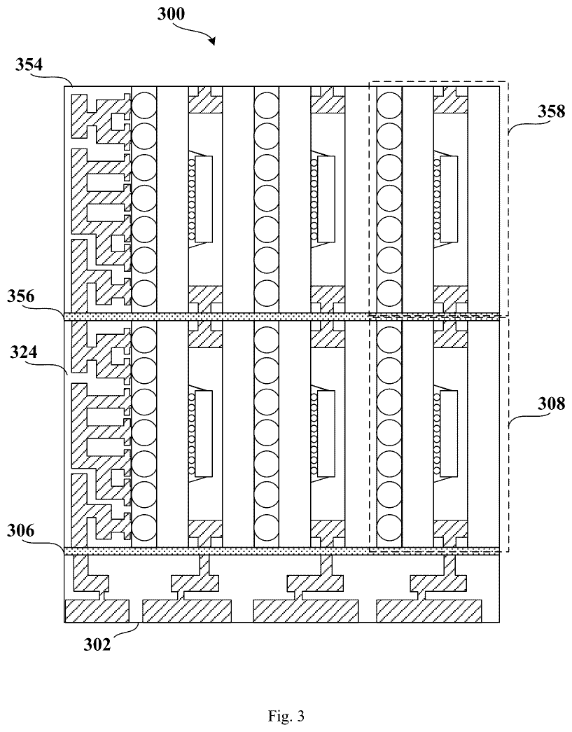

FIG. 3 illustrates a semiconductor package stack 300 according to an embodiment of the present application.

As shown in FIG. 3, the semiconductor package stack 300 includes two layers of semiconductor packages attached onto a base substrate 302. In particular, a first layer of semiconductor package 308 may be attached onto a front surface of the base substrate 302, with their respective interconnect structures aligned with each other and electrically connected with each other via a first anisotropic conductive film 306. A first vertical substrate 324 may be attached onto the base substrate 302 and besides the semiconductor package 308. Furthermore, a second layer of semiconductor packages 358 may be attached onto a top lateral surface of the semiconductor packages 308, with their respective interconnect structures aligned with each other and electrically connected with each other via a second anisotropic conductive film 356. A second vertical substrate 354 may be attached onto a top lateral surface of the first vertical substrate 324 and besides the semiconductor package 358, and at least a portion of the internal interconnect structures of the first vertical substrate 324 and the second vertical substrate 354 may be aligned with each other and electrically connected with each other via the second anisotropic conductive film 356.

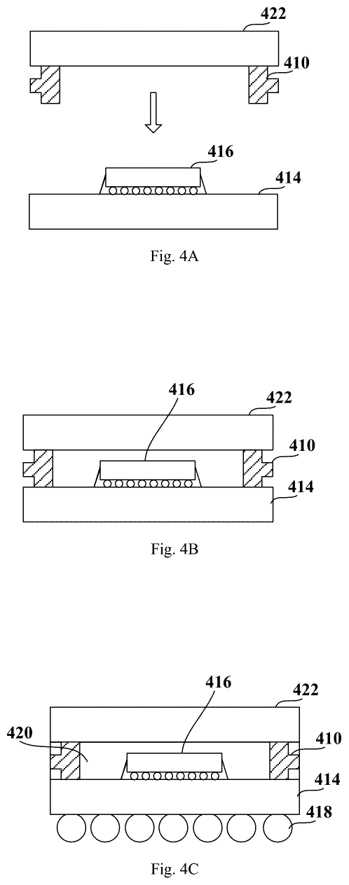

FIGS. 4A to 4C illustrate a method for forming a semiconductor package according to an embodiment of the present application. For example, the method may be used to form the semiconductor packages 108 shown in FIG. 1.

As shown in FIG. 4A, a package substrate 414 is provided, which is mounted on its front surface with one or more electronic components 416. Furthermore, an interposer 422 is provided, which has package interconnect structures 410 mounted thereon. The package interconnect structures 410 may be mounted on the interposer 422 via solder bumps (not shown), for example, to allow for electrical connection between the interposer 422 and the package interconnect structures 410. Furthermore, at least some of the package interconnect structures 410 may each have one or more branches, which have respective end surfaces that are generally aligned vertically with a lateral surface of the interposer 422. In this way, even if the package interconnect structures 410 are encapsulated within an encapsulant layer as described below, the end surfaces of the branches of the package interconnect structure 410 may be exposed from the encapsulant layer.

Next, as shown in FIG. 4B, the interposer 422 may be attached onto the package substrate 414 to dispose the package interconnect structures 410 and the one or more electronic components 416 therebetween. It can be seen that the package interconnect structures 410 may be besides the electronic components 416. Furthermore, the package interconnect structures 410 may be mounted on the package substrate 414 via solder bumps (not shown), for example, to allow for electrical connection between the package substrate 414 and the package interconnect structures 410.

Next, as shown in FIG. 4C, an encapsulant layer 420 may be formed on the front surface of the package substrate 414 to encapsulate therein the one or more electronic components 416 and the package interconnect structures 410. The encapsulant layer 420 is thus filled between the package substrate 414 and the interpose 422 to improve the firmness of the entire semiconductor package. Furthermore, package connectors 418 such as solder bumps may be mounted on a back surface of the package substrate 410, to allow further connection of the semiconductor package with another semiconductor package or a vertical substrate in a manner similar as that shown in FIG. 1 or FIG. 3.

The semiconductor package may be assembled and formed in other processes, as long as the package interconnect structures can be embedded within the semiconductor package but have at least some conductive patterns exposed from lateral surface(s) of the semiconductor package.

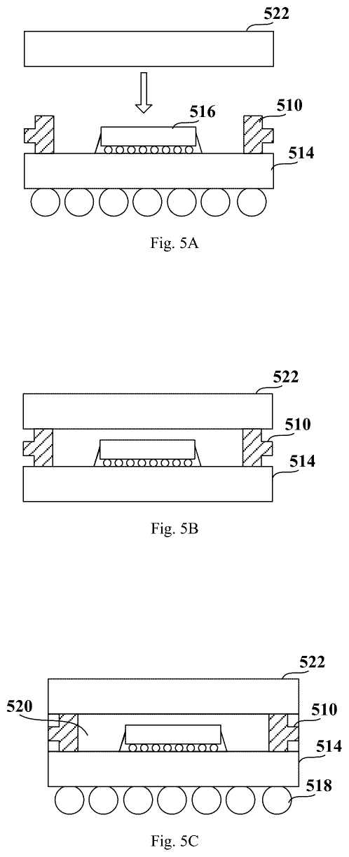

FIGS. 5A to 5C illustrate a method for forming a semiconductor package according to another embodiment of the present application. For example, the method may be used to form the semiconductor package 108 shown in FIG. 1.

As shown in FIG. 5A, a package substrate 514 and an interposer 522 are provided. The package substrate 514 is mounted on its front surface with one or more electronic components 516 and package interconnect structures 510. The package interconnect structures 510 may be disposed besides the electronic components 516, or particularly, around the electronic components 516 and close to a periphery of the package substrate 514. The package interconnect structures 510 may be mounted on the package substrate 514 via solder bumps (not shown), for example, to allow for electrical connection between the package substrate 514 and the package interconnect structures 510.

Next, as shown in FIG. 5B, the interposer 522 may be attached onto the package substrate 514 to dispose the package interconnect structures 510 and the one or more electronic components 516 therebetween. Therefore, the package interconnect structures 510 may be mounted on the interposer 522 via solder bumps (not shown), for example, to allow for electrical connection between the package substrate 514 and the interposer 522 through the package interconnect structures 510.

Next, as shown in FIG. 5C, an encapsulant layer 520 may be formed on the front surface of the package substrate 514 to encapsulate therein the one or more electronic components 516 and the package interconnect structures 510. Furthermore, package connectors 518 such as solder bumps may be mounted on a back surface of the package substrate 510, to allow further connection of the semiconductor package with another semiconductor package or a vertical substrate in a manner similar as that shown in FIG. 1 or FIG. 3.

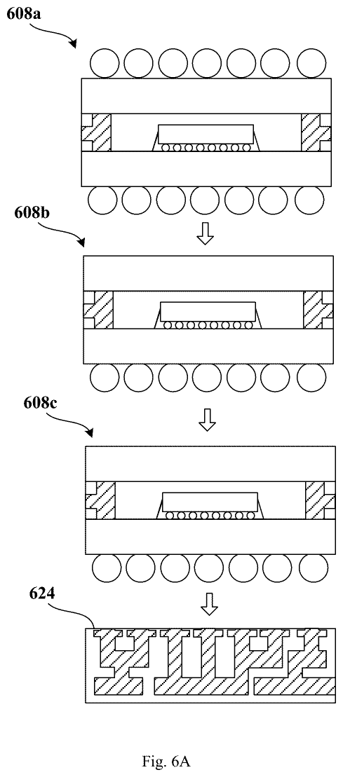

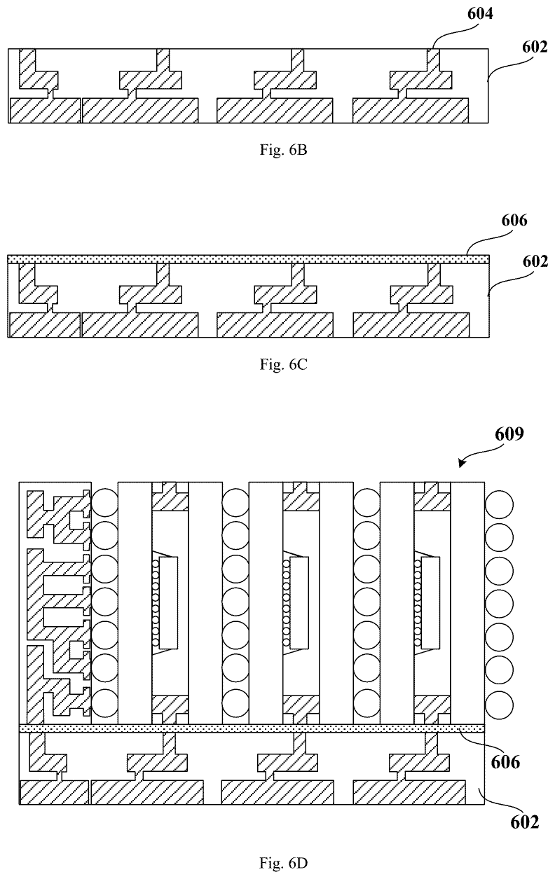

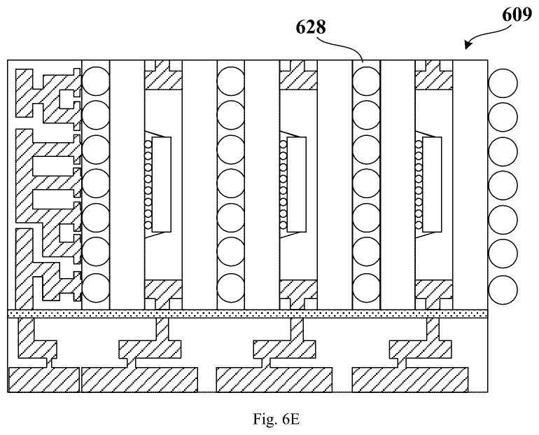

FIGS. 6A to 6E illustrate a method for forming a semiconductor package stack according to another embodiment of the present application. For example, the method may be used to assembly the semiconductor packages 108 to form a semiconductor package stack 100 shown in FIG. 1.

As shown in FIG. 6A, one or more semiconductor packages such as three semiconductor packages 608a, 608b and 608c are stacked with a vertical substrate 624, to align their respective lateral surfaces with each other in a vertical direction of FIG. 6A. Each of the semiconductor packages 608a, 608b and 608c includes a set of package interconnect structures which have a set of package conductive patterns exposed from the lateral surface of the semiconductor package 608a, 608b or 608c. Furthermore, the vertical substrate 624 includes a set of vertical conductive patterns exposed from the lateral surface of the vertical substrate 624.

Next, as shown in FIG. 6B, a base substrate 602 is provided. The base substrate 602 may have one or more sets of base conductive patterns 604 on its front surface. Afterwards, as shown in FIG. 6C, an anisotropic conductive film 606 may be formed on the front surface of the base substrate 602.

Next, as shown in FIG. 6D, the stack 609 of the semiconductor packages 608a, 608b and 608c and the vertical substrate 622 may be laid down, with its lateral surfaces aligned with the horizontal direction of FIG. 6D. Then the stack 609 may be attached onto the front surface of the base substrate 602 via the anisotropic conductive film 606, such that the sets of package conductive patterns and the set of vertical conductive patterns on the respective lateral surfaces of the semiconductor packages 608a, 608b and 608c and the vertical substrate 624 are aligned with the one or more sets of base conductive patterns on the front surface of the base substrate 602. Furthermore, the anisotropic conductive film 606 may be cured, for example, by thermal compression bonding, to allow electrical connection between the base conductive patterns and the package interconnect structures. As aforementioned, the thermal compression bonding can help aggregate conductive particles in the anisotropic conductive film 606 in its thickness direction and thus provide vertical electrical paths that are sufficient for signal transmission between the semiconductor packages 608a to 608c, the vertical substrate 624 and the base substrate 602. Furthermore, the thermal compression bonding also helps warpage control of the base substrate 602. It can be appreciated other curing process may be used, depending on the material of the anisotropic conductive film 606.

Afterwards, as shown in FIG. 6E, an insulative filler material 628 may be filled around each set of package connectors internal to the stack 609 of semiconductor packages, to provide insulation and protection for the package connectors. In some alternative embodiments, the insulative filler material 628 may be filled around the package connectors of the semiconductor packages prior to the attachment of the stack 609 to the base substrate, i.e., after the step shown in FIG. 6A. In this way, a semiconductor package stack may be formed.

The discussion herein included numerous illustrative figures that showed various portions of a semiconductor package stack and a method for forming a semiconductor package stack of the present application. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package stack, comprising:
a base substrate having one or more sets of base conductive patterns on its front surface;
an anisotropic conductive film formed on the front surface of the base substrate;
one or more semiconductor packages disposed on the base substrate via the anisotropic conductive film and extending vertically relative to the front surface of the base substrate, wherein each of the one or more semiconductor packages comprises a set of package interconnect structures which have a set of package conductive patterns exposed from a lateral surface of the semiconductor package; and wherein the set of package conductive patterns are aligned with a set of base conductive patterns to allow electrical connection therebetween via the anisotropic conductive film; and
a vertical substrate disposed on the base substrate via the anisotropic conductive film and extending vertically relative to the front surface of the base substrate, wherein the vertical substrate comprises a set of vertical interconnect structures which have a set of vertical conductive patterns exposed from a lateral surface of the vertical substrate; and wherein the set of vertical conductive patterns are aligned with a set of base conductive patterns to allow electrical connection therebetween via the anisotropic conductive film.

2. The semiconductor package stack of claim 1, wherein each of the one or more semiconductor packages comprises:
a package substrate having one or more electronic components mounted on its front surface and package connectors mounted on its back surface;
an encapsulant layer formed on the front surface of the package substrate and for encapsulating therein the one or more electronic components and the package interconnect structures; and
an interposer disposed on a front surface of the encapsulant layer;
wherein the set of package conductive patterns of the set of package interconnect structures are exposed from a lateral surface of the encapsulant layer, and the interposer and the package substrate are electrically coupled to each other via the set of package interconnect structures.

3. The semiconductor package stack of claim 2, wherein the vertical interconnect structures are electrically connected to the package connectors of the semiconductor package adjacent to the vertical substrate.

4. The semiconductor package stack of claim 2, wherein the package connectors of each semiconductor package are electrically connected to the interposer of another semiconductor package adjacent to the semiconductor package.

5. The semiconductor package stack of claim 1, wherein the lateral surface of the semiconductor package is a first lateral surface, and wherein each of the one or more semiconductor packages further comprises at least one another set of package interconnect structures each of which have another set of base conductive patterns exposed from a second lateral surface of the semiconductor package.

6. The semiconductor package stack of claim 1, wherein each package interconnect structure comprises a metal pillar with at least one branch.

7. The semiconductor package stack of claim 1, further comprising:
an insulative filler material around each set of package connectors internal to the semiconductor package stack.

8. A method for forming a semiconductor package stack, wherein the method comprises:
stacking one or more semiconductor packages with a vertical substrate, to align their respective lateral surfaces with each other in a horizontal direction, wherein each of the semiconductor packages comprises a set of package interconnect structures which have a set of package conductive patterns exposed from the lateral surface of the semiconductor package; and the vertical substrate comprises a set of vertical conductive patterns exposed from the lateral surface of the vertical substrate;
providing a base substrate having one or more sets of base conductive patterns on its front surface;
forming an anisotropic conductive film on the front surface of the base substrate; and
attaching vertically the stack of the one or more semiconductor packages and the vertical substrate onto the front surface of the base substrate via the anisotropic conductive film, such that the sets of package conductive patterns and the set of vertical conductive patterns on the respective lateral surfaces of the one or more semiconductor packages and the vertical substrate are aligned with the one or more sets of base conductive patterns on the front surface of the base substrate to allow electrical connection therebetween via the anisotropic conductive film.

9. The method of claim 8, wherein each of the semiconductor package is formed using the following steps:
providing a package substrate having one or more electronic components mounted on its front surface;
providing an interposer having the package interconnect structures mounted thereon;
attaching the interposer onto the package substrate with the package interconnect structures disposed besides the one or more electronic components;
forming an encapsulant layer on the front surface of the package substrate to encapsulate therein the one or more electronic components and the package interconnect structures; and
forming package connectors mounted on a back surface of the package substrate.

10. The method of claim 8, wherein each of the semiconductor package is formed using the following steps:
providing a package substrate having one or more electronic components and the package interconnect structures mounted on its front surface;
providing an interposer;
attaching the interposer onto the package substrate with the package interconnect structures and the one or more electronic components disposed between the interposer and the package substrate;
forming an encapsulant layer on the front surface of the package substrate to encapsulate therein the one or more electronic components and the package interconnect structures; and
forming package connectors mounted on a back surface of the package substrate.

11. The method of claim 9, wherein each package interconnect structure comprises a metal pillar with at least one branch.

12. The method of claim 10, wherein each package interconnect structure comprises a metal pillar with at least one branch.

13. The method of claim 8, further comprising:
forming an insulative filler material around each set of package connectors internal to the stack of semiconductor packages.
